(19) United States
(12) Patent Application Publication
(10) Pub. No.: US 2026/0095166 A1
(43) Pub. Date: Apr. 2, 2026

(54) CONSISTENCY CHECKING CIRCUIT FOR COMPONENTS WITH INTERNAL CLOCKING

(71) Applicant: Arm Limited, Cambridge (GB)

(72) Inventors: Nicolaas Klarinus Johannes van Winkelhoff, Roquefort-les-pins (FR); Nicolas Patrick Alain Garnier, Biot (FR)

(21) Appl. No.: 18/904,594

(22) Filed: Oct. 2, 2024

(51) Int. Cl. H03K 5/1252; H03K 5/135; H03K 5/1534

(52) U.S. Cl. CPC H03K 5/1252; H03K 5/135; H03K 5/1534

(57) ABSTRACT

A consistency checking circuit can include a dynamic input comparator structured to compare dynamic signals received at a first input and a second input to detect an inconsistency on an internal clock line of a component with respect to a signal from an external clock line, wherein the dynamic input comparator is coupled at the first input to the internal clock line and coupled at the second input to an external clock line of the component. The detected inconsistency can be a glitch on the internal clock line, a slew, or an inconsistent sequence of transitions.

### BACKGROUND

Components with internal clocking can suffer from misoperation caused by an erroneous signal on the internal clock line. Erroneous signals, whether intentional or unintentional, can arise due to glitches, skew, or incorrect transition sequences on the internal clock line. For a component with internal clocking such as certain memory circuitry, misoperation can result in loss of data (due, for example, to overwriting of memory locations) and leakage of data.

### BRIEF SUMMARY

Consistency checking circuits for components with internal clocking are described. A consistency checking circuit can be incorporated in a component with internal clocking by being coupled to both an external clock line and an internal clock line for the component.

A consistency checking circuit can include a dynamic input comparator structured to compare dynamic signals received at a first input and a second input to detect an inconsistency on an internal clock line of a component with respect to a signal from an external clock line, wherein the dynamic input comparator is coupled at the first input to the internal clock line and coupled at the second input to an external clock line of the component. The detected inconsistency can be a glitch on the internal clock line, a slew, or an inconsistent sequence of transitions.

An apparatus can include a component with internal clocking; and a dynamic input comparator structured to compare dynamic signals received at a first input and a second input to detect an inconsistency on an internal clock line of the component with respect to a signal from an external clock line. The component can include logic circuitry structured to combine an external clock signal with a component enable signal and output the signal from the external clock line that is used as an input of the dynamic input comparator.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

### BRIEF DESCRIPTION OF THE DRAWINGS

FIG. 1 shows a representation of a consistency checking circuit for a component with internal clocking.

FIGS. 2A and 2B show example implementations of a dynamic input comparator of a consistency checking circuit.

FIG. 3 shows an example operating environment of a consistency checking circuit.

FIGS. 4A and 4B show example representations of consistency checking circuits for components with internal clocking based on multiple external clocks.

FIG. 5 shows an example implementation of a memory incorporating a consistency checking circuit as described herein.

### DETAILED DESCRIPTION

Consistency checking circuits for components with internal clocking are described. A consistency checking circuit can be incorporated in a component with internal clocking by being coupled to both an external clock line and an internal clock line for the component. Since the signals on clock lines constantly toggle, the consistency checking circuit includes a dynamic input comparator that compares an external clock signal from the external clock line to an internal clock signal from the internal clock line and provides an output indicative of whether the two signals are consistent or inconsistent. A detected inconsistency can be a glitch on the internal clock line, a slew, or an inconsistent sequence of transitions. In this manner, the consistency checking circuit can identify unexpected/illegitimate behavior on the internal clock line.

Glitches arise in electronic systems due to temporary fluctuations in a signal that occur as a result of various factors including timing issues and malicious or inadvertent signal injection. Glitches in a signal path may cause errors in operation of a circuit, for example, creating incorrect logic values at downstream components. Glitches in a clock path may cause errors in operations of the circuit, for example, causing operation of the circuit at a time the circuit should not be operating, which can cause operations to occur downstream as well as create a drain on power. For example, a glitch on an internal clock of a memory can expose data or alter data in a storage element.

Slew refers to a rate of change of a voltage per unit of time, which indicates the time it takes to switch from a 0 to a 1 or from a 1 to a 0. Clock skew, which is the delay in clock delivery between synchronous elements, can be affected by differences in the slew of two clocks. Changes to slew rate and resulting clock skew have a number of different causes, including altered capacitance and/or extra gates (intentionally or inadvertently included) in one of the paths that cause unbalanced load.

A sequence of transitions refers to the changes of states between 0 and 1 from a previous state to a next state. An inconsistent transition sequence can be detected when a pulse duration of one signal (e.g., external clock) is of a different duration than the other signal (e.g., internal clock), reflecting changes of states occurring between receipt of a next input or external clock pulse.

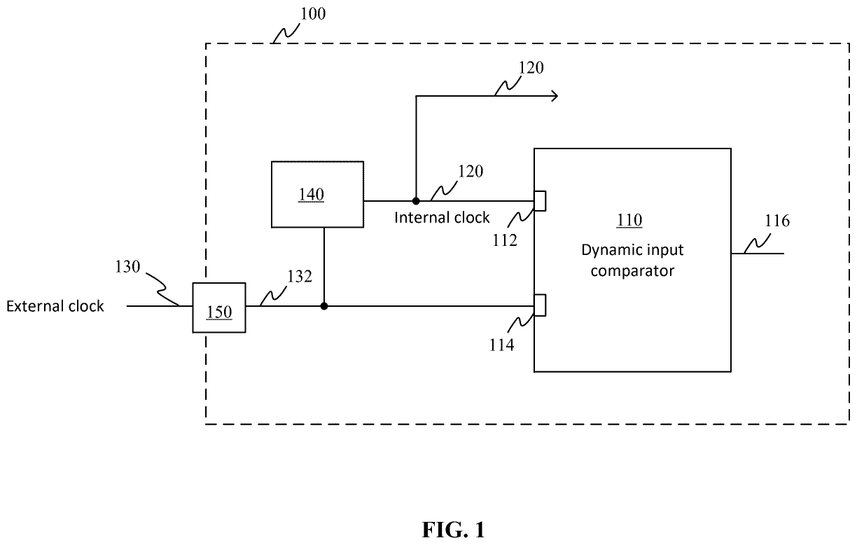

FIG. 1 shows a representation of a consistency checking circuit for a component with internal clocking. Referring to FIG. 1, a component 100 with internal clocking can include a consistency checking circuit in the form of a dynamic input comparator 110. The dynamic input comparator 110 is structured to compare dynamic signals received at a first input 112 and a second input 114 to detect an inconsistency on an internal clock line 120 of the component 100 with respect to a signal 132 from an external clock line 130 to the component 100. Examples of components with internal clock lines include, but are not limited to, memory circuitry, components that include memory circuitry, and certain analog circuitry. Examples of memory circuitry include static random access memory (SRAM) circuitry, dynamic random access memory (DRAM), magnetic random access memory (MRAM), read only memory (ROM), register files, or any other memory that has internal clock circuitry receiving an external clock signal to supply an internal clock signal to particular function blocks. The analog circuitry can include sampling circuits, for example, a watchdog timer or a sample-and-hold circuit with internal clocking utilizing a reduced or increased frequency.

The internal clock line 120 can be coupled to clock circuitry 140 that generates an internal clock signal on the internal clock line based on the signal 132 from the external clock line 130 to the component 100. Clock circuitry 140 can be a pulse generator circuit, a filter (e.g., in the form of a transistor and/or capacitor), logic circuitry, or other element enabling an internal clock to be synchronized to an external clock.

The dynamic input comparator 110 is coupled at the first input 112 to the internal clock line 120 and coupled at the second input 114 to the external clock line 130 of the component 100. Dynamic input comparator 110 compares an external clock signal from the external clock line 130 to an internal clock signal from the internal clock line 120 and provides an output 116 indicative of whether the two signals are consistent or inconsistent. In some cases, two output lines are provided—one for signaling a consistent result and one for signaling an inconsistent result. In some cases, one output line is provided—with the line going high or low depending on the result.

The second input 114 can be directly connected to external clock line 130 or connected to the external clock line 130 through another component. For example, in some cases, logic circuitry 150 can be included to combine an external clock signal with a component enable signal or other input signal used to start an operation. In such cases, logic circuitry 150 outputs the signal 132 from the external clock line 130 such that the second input 114 of the dynamic input comparator 110 is coupled to the external clock line 130 through the logic circuitry 150. An example of logic circuitry 150 is an AND gate. In various implementations, logic circuitry 150 can include a logic gate such as an AND gate, NOR gate, OR gate, and multiples and combinations thereof.

Since the signals on clock lines constantly toggle, dynamic input comparator 110 is designed to enable a comparison of two dynamic inputs.

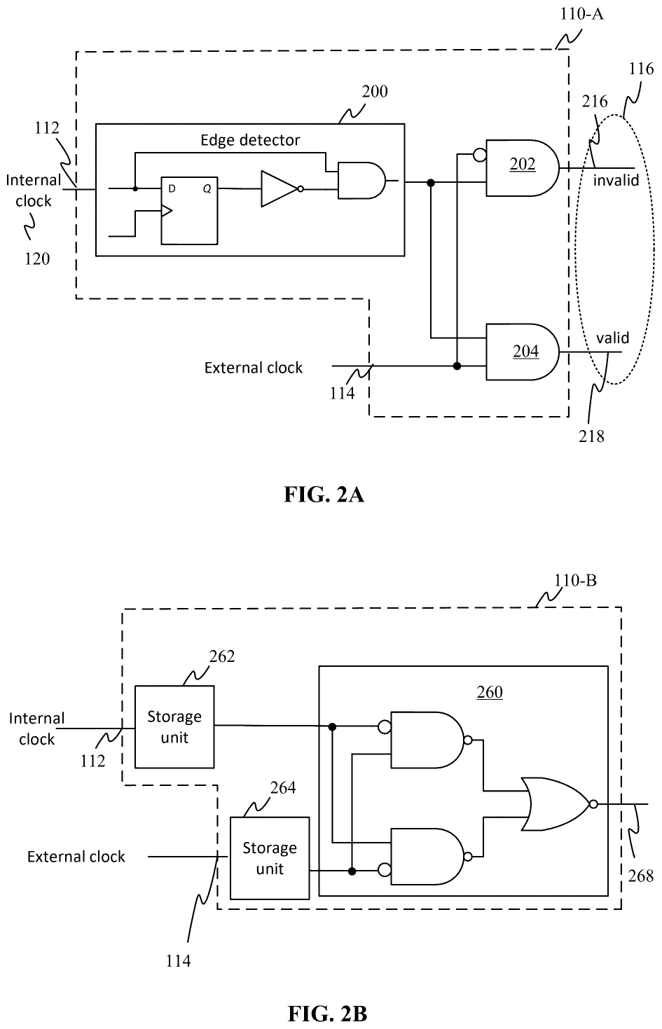

FIGS. 2A and 2B show example implementations of a dynamic input comparator of a consistency checking circuit. As illustrated in FIGS. 2A and 2B, it is possible to compare dynamic signals and produce an output indicative of whether the two signals are consistent or inconsistent by using logic gates and an edge detector or by using a digital comparator and circuitry that can hold a value (e.g., a storage unit such as a latch).

Referring to FIG. 2A, dynamic input comparator 110-A includes an edge detector circuit 200 structured to receive an internal clock signal from the first input 112; a first AND gate 202 having an inverted input and a regular input; and a second AND gate 204. An output of the edge detector circuit 200 is coupled to the regular input of the first AND gate 202 and one input of the second AND gate 204. The inverted input of the first AND gate 202 and one other input of the second AND gate 204 are coupled to the external clock line from the second input 114. It should be understood that while AND gates are shown in the illustrated implementation, these AND gates 202, 204 can be replaced with an OR with appropriate inverter input(s) and output(s) as is known in the art to provide similar logic operations.

In some cases, the edge detector circuit 200 is a rising edge detector. In some cases, the edge detector circuit 200 is a falling edge detector. The edge detector circuit 200 can include a trim input so as to avoid triggering detection if amplitude or timing is not above a sufficient threshold. Examples of trimming circuitry for the trim input of the edge detector circuit 200 include, but are not limited to, a LC filter, a Schmitt trigger, or configurable delay chain.

As shown in FIG. 2B, the output 116 is produced on separate lines—one line 216 that goes high/low for an invalid result and one line 218 that goes high/low for a valid result. A high output (logical 1) of the first AND gate 202 (e.g., at line 216) indicates the detection of an inconsistency on the internal clock line 120 and a high output (logical 1) of the second AND gate 204 (e.g., at line 218) indicates that no inconsistency is detected. By providing two output lines, it is possible to have circuitry that uses a report of a valid activation to trigger an action and separate circuitry that uses a report of invalid activation to trigger an action by that separate circuitry.

Referring to FIG. 2B, dynamic input comparator 110-B includes a digital comparator 260; a first storage unit 262 coupled to the internal clock line 120 from the first input 112 to capture a value indicating a received pulse; and a second storage unit 264 coupled to the external clock line 130 from the second input 114 to capture a corresponding value indicating a received clock. The digital comparator 260 compares the value stored in the first storage unit 262 with the corresponding value from the second storage unit 264 and outputs a non-matching signal 268 (e.g., output signal goes high) when the value stored in the first storage unit 262 and the corresponding value stored in the second storage unit 264 do not match. The non-matching signal 268 indicates the detection of the inconsistency on the internal clock line 120. The first storage unit 262 and the second storage unit 264 can be latches.

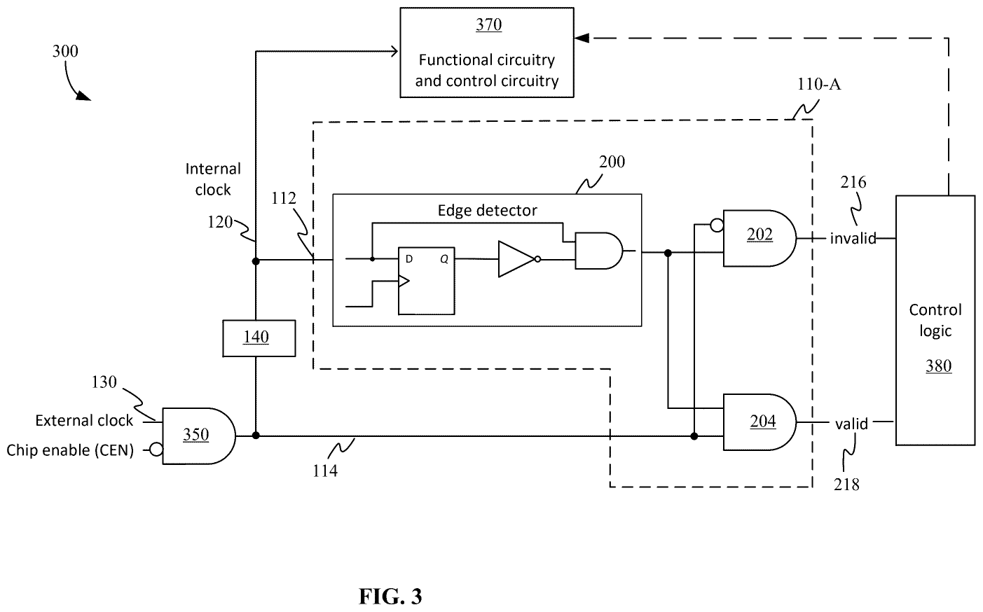

FIG. 3 shows an example operating environment of a consistency checking circuit. Referring to FIG. 3, an apparatus can include a component 300 with internal clocking. In the illustrated example, component 300 receives the external clock signal and a component enable signal (CEN) for controlling operation of the component 300. The external clock signal and component enable signal are combined by AND gate 350, which is shown having an inverting input for receiving an active low CEN signal. An internal clock line 120 is used to provide an internal clock for functional circuitry 370 of component 300. For example, when component 300 is a memory circuitry, the internal clock can be used by the control circuitry of the memory circuitry as clock input synchronizing operations of functional circuitry including the wordline driver, read circuitry, and write circuitry. Misoperation of component 300 resulting from signals on the internal clock line can be identified by a consistency checking circuit in the form of dynamic input comparator 110-A as described with respect to FIG. 2A. Control logic 380 is coupled to the dynamic input comparator 110-A to receive the outputs (e.g., at lines 216 and 218) of the dynamic input comparator 110-A.

Dynamic input comparator 110-A compares the dynamic signals received at its first input 112 and second input 114 to detect an inconsistency on the internal clock line 120 of the component 300 with respect to the signal from the external clock line 130. A high output (logical 1) of the first AND gate 202 (e.g., at line 216) indicates the detection of an inconsistency on the internal clock line 120 and a high output (logical 1) of the second AND gate 204 (e.g., at line 218) indicates that no inconsistency is detected.

Thus, a result of the consistency checking circuit can be used by control logic 380 of component 300 for a variety of actions. Control logic 380 may be existing control circuitry of component 300 (where the signal(s) received from the consistency checking circuit trigger certain operations already available) or be additional circuitry to enable certain operations based on the signal(s) received from the consistency checking circuit.

The operations triggered by signals of the outputs of the consistency checking circuit can depend on desired functionality and design for the component. For example, control logic 380 can trigger a restart function of the component 300 in response to the output of the dynamic input comparator 110-A indicating the inconsistency is detected on the internal clock line 120. As another example, control logic 380 can trigger a shutdown of at least the component 300 in response to the output of the dynamic input comparator 110-A indicating the inconsistency is detected on the internal clock line 120. As yet another example, control logic 380 can trigger a change to a state of the component 300 in response to the output of the dynamic input comparator 110-A indicating the inconsistency is detected on the internal clock line. As yet another example, control logic 380 can trigger a change to stored data of the component 300 in response to the output of the dynamic input comparator 110-A indicating the inconsistency is detected on the internal clock line.

For example, when the component is a memory, the operations can include, but are not limited to, pipeline flush (for CPU), data integrity check, memory rewrite, corruption of the memory, and generation of a new security encryption key. In some cases, the signal on the valid output line 218 can be an input to enable operations of component 300 (e.g., in a similar manner as with CEN for the component 300). Similar operations are possible with a single output line such as for the dynamic input comparator 110-B. In some cases, the signal on the invalid output line 216 can be an input to enable operations of a component. For example, for an analog circuit such as a watchdog timer or a sample-and-hold circuit, the invalid signal from invalid output line 216 can be used to indicate valid operation even as the external clock trails in triggering. Similar operations are possible with a single output line such as for the dynamic input comparator 110-B.

All or some of these operations (and others not described) may be included, depending on embodiment. For example, the output signals “valid” and “invalid” can be latched in a kill-switch (requiring a restart of chip), latched in a valid/invalid bit that is reset every legal clock, or non-latched and used as an asynchronous (in)valid check, among other operations. Invalid signals can trigger operations such as repair, rewrite, CPU pipeline flush, security flag, regeneration and storage of a secure code-key, and declaration of memory content as invalid.

Although examples and illustrations are shown for components with internal clocking based on one external clock line, the above-described configurations are applicable to components with internal clocking based on multiple external clocks.

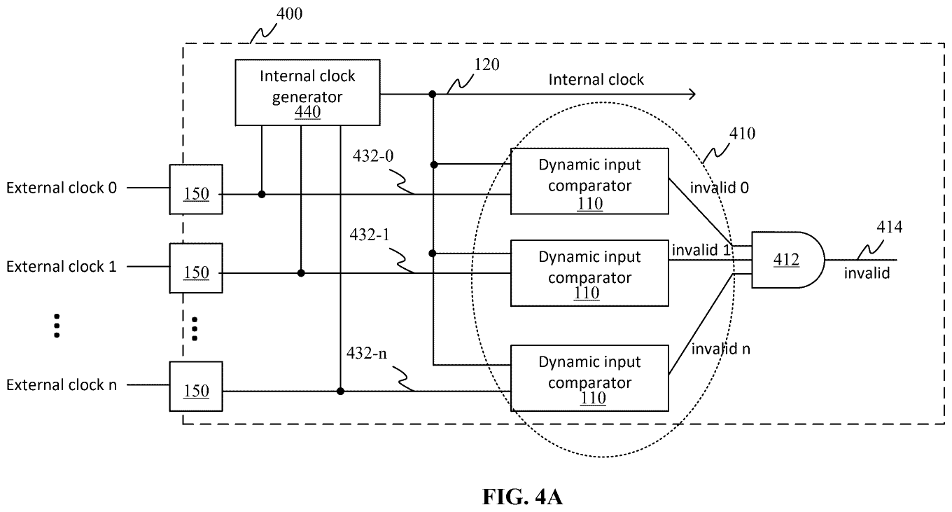

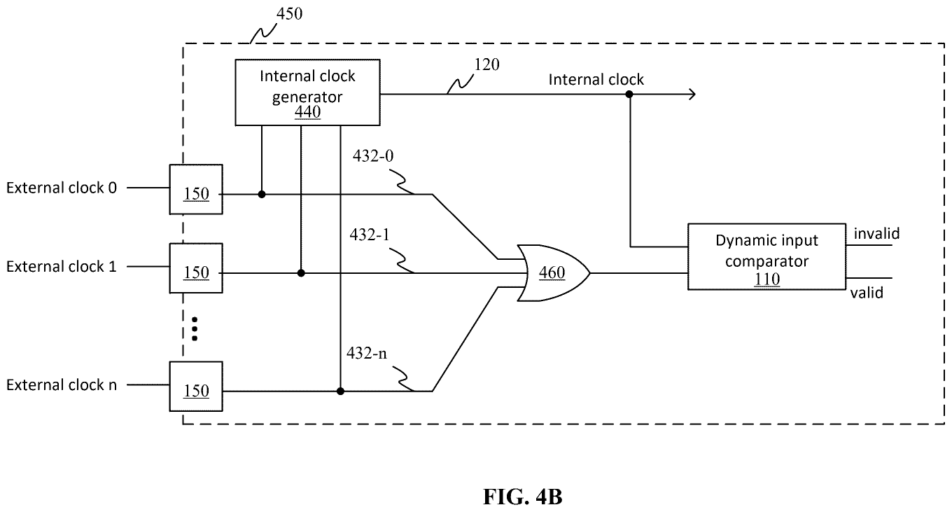

FIGS. 4A and 4B show example representations of consistency checking circuits for components with internal clocking based on multiple external clocks.

Referring to FIG. 4A, component 400 includes a consistency checking circuit for an internal clock generator 440 that is based on multiple external clocks (e.g., external clock 0, external clock 1, . . . , external clock n). Here, the consistency checking circuit includes a plurality of dynamic input comparators 410 and a logic gate 412 (e.g., AND gate) that combines outputs of the plurality of dynamic input comparators 410. Each comparator of the plurality of dynamic input comparators 410 can be in the form of dynamic input comparator 110 as described with respect to FIGS. 1, 2A, and 2B. Each dynamic input comparator 110 of the plurality of dynamic input comparators 410 compares an internal clock to one of a plurality of external clock signals (signals 432-0, 432-1, . . . , 432-n from the external clock lines (external clock 0, external clock 1, . . . , external clock n)). In the illustrated implementation, an output of each dynamic input comparator 110 that indicates the inconsistency is used (labeled “invalid 0” to “invalid n”) and combined at the logic gate 412 to provide an output 414 indicative of whether there is an inconsistency between at least one of the external clock signals and the internal clock (output labeled “invalid”).

Each dynamic input comparator 110 can have an input directly connected to the corresponding external clock line or is connected to the corresponding external clock line through another component. For example, in some cases, logic circuitry 150 can be included to combine an external clock signal of one or more of the external clock lines with a component enable signal or other input signal used to start an operation. Logic circuitry 150 can include a logic gate such as an AND gate, NOR gate, OR gate, and multiples and combinations thereof.

Component 400 can be or include memory circuitry and/or analog circuitry as described with respect to component 100 of FIG. 1. Here, component 400 has an internal clock generator 440 that generates an internal clock signal on the internal clock line 120 based on signals 432-0, 432-1, . . . , 432-n from the external clock lines (external clock 0, external clock 1, . . . , external clock n). Internal clock generator 440 can be a pulse generator circuit, a filter (e.g., in the form of a transistor and/or capacitor), logic circuitry, or other element enabling an internal clock to be synchronized to one or more external clocks.

Accordingly, in certain implementations, an apparatus can include a dynamic input comparator 110 structured to compare dynamic signals received at a first input and a second input to detect an inconsistency on an internal clock line of a component with respect to a signal from an external clock line, wherein the dynamic input comparator is coupled at the first input to the internal clock line and coupled at the second input to an external clock line of the component; at least one additional dynamic input comparator 110 (the dynamic input comparator and the at least one additional dynamic input comparator forming a plurality of dynamic input comparators 410), wherein each additional dynamic input comparator of the at least one additional dynamic input comparator is coupled to the internal clock line and a corresponding additional external clock line of the plurality of external clock lines; and a logic gate 412 coupled to the dynamic input comparator and the at least one additional dynamic input comparator to combine outputs of the dynamic input comparator and the at least one additional dynamic input comparator.

Referring to FIG. 4B, similar to component 400, component 450 includes a consistency checking circuit for an internal clock generator 440 that is based on multiple external clocks (e.g., external clock 0, external clock 1, . . . , external clock n). However, in the implementation shown in FIG. 4B, instead of a plurality of dynamic input comparators 410, one dynamic input comparator 110 can be used for a plurality of external clock signals in order to output a signal indicative of whether there is an inconsistency between at least one of the external clock signals and the internal clock (outputs labeled “invalid” and “valid”). Here, a logic gate 460 is used to combine a plurality of external clock signals (e.g., signals 432-0, 432-1, . . . , 432-n from the external clock lines (external clock 0, external clock 1, . . . , external clock n)) before being compared with an internal clock signal on the internal clock line 120 by the dynamic input comparator 110. The logic gate 460 can be directly connected to the corresponding external clock line or is connected to the corresponding external clock line through another component such as logic circuitry 150.

Accordingly, in certain implementations, an apparatus can include a dynamic input comparator 110 structured to compare dynamic signals received at a first input and a second input to detect an inconsistency on an internal clock line of a component with respect to a signal from an external clock line, wherein the dynamic input comparator is coupled at the first input to the internal clock line and coupled at the second input to an external clock line of the component; and a logic gate 460 coupled to a plurality of external clock lines including the external clock line to combine signals from the plurality of external clock lines, wherein the dynamic input comparator is coupled at the second input to the external clock line of the component and to other external clock lines of the plurality of external clock lines via an output of the logic gate, whereby the dynamic input comparator detects the inconsistency on the internal clock line of the component with respect to the signal from the external clock line and any other signal from the other external clock lines of the plurality of external clock lines.

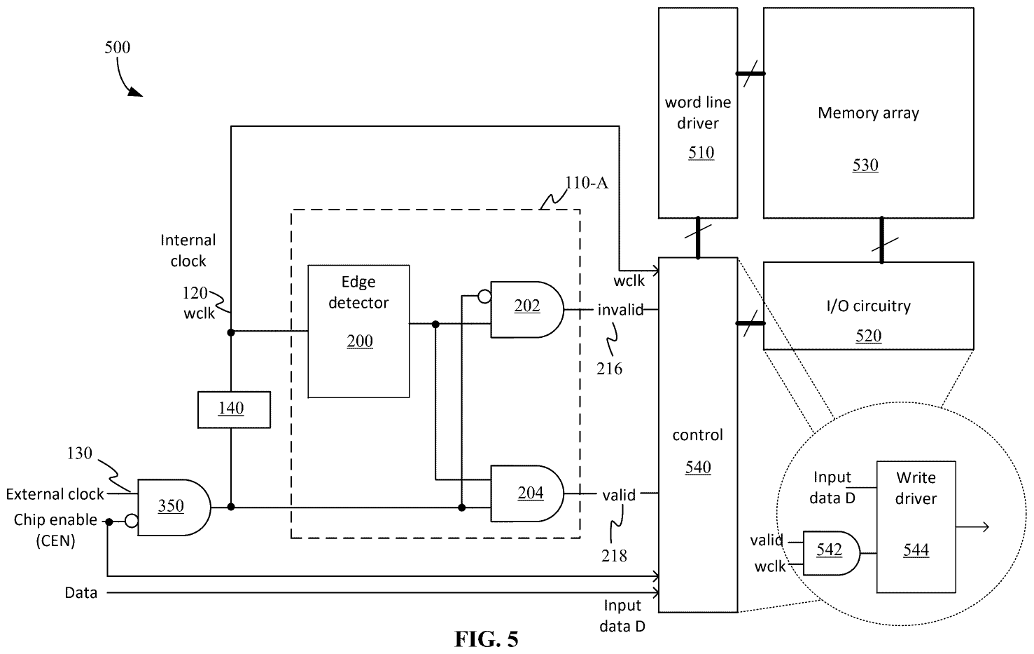

FIG. 5 shows an example implementation of a memory incorporating a consistency checking circuit as described herein. Referring to FIG. 5, memory 500 includes a word line driver 510, input/output circuitry 520, a memory array 530, and a control circuit. The word line driver 510 and the input/output circuitry 520 operate under the control of the control circuit 540 so as to read data from and write data to the memory array 530.

The memory array 530 is structured as an array of memory cells with rows accessed by word lines via the word line driver 510 and columns accessed by bit lines via the input/output circuitry 520. In certain implementations, the memory 500 is a static random access memory (SRAM).

As part of, or in conjunction with, control circuit 540, logic circuitry (e.g., AND gate 350), internal clock circuitry 140, and a dynamic input comparator 110-A are provided. The memory 500 receives a chip enable signal, an external clock signal, an address, and, for performing a write operation, data. The chip enable signal indicates a start of an operation for the memory 500. The external clock signal provides the operating frequency for the circuitry. In the illustrated implementation, the logic circuitry (e.g., AND gate 350) receives the chip enable signal and the external clock signal. In some cases, the chip enable signal may also be used as input to other circuitry of the control circuit 540. Internal clock circuitry receives the external clock signal (e.g., as provided by the AND gate 350) and generates an internal clock signal, such as wclk, on the internal clock line 120. The dynamic input comparator 110-A is used to detect an inconsistency on the internal clock line 120 of the memory 500 with respect to the external clock signal. In the illustrated scenario, the control circuit 540 receives the outputs indicative of a valid and invalid signal on the internal clock line 120 and uses the signals on the outputs of the dynamic input comparator 110-A to perform certain actions.

In particular, control circuit 540 generates outputs to control the word line driver 510 and the input/output circuitry 520. The word line driver 510 receives the address and turns on a word line indicated by the address based on a word line enable signal from the control circuit 540. The input/output circuitry 520 includes write circuitry and read circuitry, which are operated by control signals generated by the control circuit 540 based, at least in part, on the internal clock signal (e.g., wclk) and the output(s) of the dynamic input comparator 110-A. For example, control circuit 540 and input/output circuitry 520 can include an AND gate 542 and write driver 544 as part of the circuitry supporting a write operation. Here, the valid output line 218 of the dynamic input comparator 110 and the internal clock signal wclk are used to control whether write driver 544 for input data is operated so as to support writing the input data to a memory cell. If there were to be a glitch (or slew or inconsistent sequence) on the internal clock signal wclk, it could be possible that unintended data is driven to a memory cell, causing overwrites. However, with the inclusion of the dynamic input comparator 110-A, so long as the signal on the valid output line 218 remains high, indicating that the internal clock signal is consistent with the external clock signal, the write driver 544 can be operated. Similar to the write operation, in the case of a read operation, an internal clock signal can drive a sense amplifier enable signal, which enables a sense amplifier to capture a value on a selected bitline.

For example, for a read operation in a memory such as SRAM, the address of a storage location for a word is transferred to an address line, a pre-charge circuit is used to bring bitlines to a first voltage, the wordline is driven high (pre-charge circuit is turned off), the cells storing the data at the storage location pull down one bitline, and a sense circuit of the read circuitry located on a periphery of the memory array is activated to capture the value on the bitlines. In detail, the read cycle may be started by precharging the bitlines (e.g., bitline and bitline bar of each bitcell). When a wordline is asserted, the access transistors of a cell are enabled, which can cause one bitline voltage to slightly drop, resulting in a small voltage difference between the bitline and bitline bar. A sense amplifier can sense which line has the higher voltage and thus determine whether there was 1 or 0 stored. The sense amplifier enable signal allows for the readout of the sense amplifier.

Thus, when an external clock signal and external enable signal (e.g., chip enable signal) generates the internal clock signals driving the activation to read data stored in the data array (e.g., the sense amplifier enable signal), if there is an inconsistency regarding internal clock signals, it could be possible that data is unintentionally acceded out of the memory. However, by using an output of a dynamic input comparator as described herein (e.g., such as implemented by AND gate 542 in the above example [symbol] , it is possible to block the memory from reading so that no data is inadvertently presented at the output (Q) of the memory. Similarly, in the case of dual access memory, the above-described scenarios for write and read operations can be combined.

It should of course be understood that the example configuration of FIG. 5 is merely illustrative of how one implementation of a dynamic input comparator can be incorporated into a memory.

Certain embodiments of the illustrated circuitry and components include the following.
Clause 1. An apparatus comprising: a dynamic input comparator structured to compare dynamic signals received at a first input and a second input to detect an inconsistency on an internal clock line of a component with respect to a signal from an external clock line, wherein the dynamic input comparator is coupled at the first input to the internal clock line and coupled at the second input to an external clock line of the component.
Clause 2. The apparatus of clause 1, wherein the internal clock line is coupled to clock circuitry that generates an internal clock signal on the internal clock line based on a signal from the external clock line.
Clause 3. The apparatus of clauses 1 or 2, wherein the inconsistency on the internal clock line of the component with respect to the signal from the external clock line is a glitch on the internal clock line, a slew, or an inconsistent sequence of transitions.
Clause 4. The apparatus of any of clauses 1-3, further comprising: logic circuitry structured to combine an external clock signal with a component enable signal and output the signal from the external clock line, wherein the second input of the dynamic input comparator is coupled to the external clock line through the logic circuitry.
Clause 5. The apparatus of any of clauses 1-4, wherein the dynamic input comparator comprises: an edge detector circuit structured to receive an internal clock signal from the first input; a first AND gate having an inverted input and a regular input; and a second AND gate, wherein an output of the edge detector circuit is coupled to the regular input of the first AND gate and one input of the second AND gate, wherein the inverted input of the first AND gate and one other input of the second AND gate are coupled to the external clock line from the second input, wherein a first output of the first AND gate indicates detection of an inconsistency on the internal clock line.
Clause 6. The apparatus of clause 5, wherein the edge detector circuit is a rising edge detector.
Clause 7. The apparatus of clause 5, wherein the edge detector circuit is a falling edge detector.
Clause 8. The apparatus of clause 5, wherein the edge detector circuit comprises a trim input including a LC filter, Schmitt trigger, or configurable delay chain.
Clause 9. The apparatus of any of clauses 1-4, wherein the dynamic input comparator comprises: a digital comparator; a first storage unit coupled to the internal clock line from the first input to capture a value indicating a received pulse; and a second storage unit coupled to the external clock line from the second input to capture a corresponding value indicating a received clock, wherein the digital comparator compares the value stored in the first storage unit with the corresponding value from the second storage unit and outputs a non-matching signal when the value and the corresponding value do not match, wherein the non-matching signal indicates the inconsistency on the internal clock line.
Clause 10. The apparatus of clause 9, wherein the first storage unit and the second storage unit comprise latches.
Clause 11. The apparatus of any preceding clause, further comprising the component.
Clause 12. The apparatus of clause 11, wherein the component comprises memory circuitry.
Clause 13. The apparatus of clause 11, wherein the component comprises analog circuitry.
Clause 14. The apparatus of any preceding clause, further comprising: control logic coupled to the dynamic input comparator to receive an output of the dynamic input comparator, the output of the dynamic input comparator indicating whether the inconsistency is detected on the internal clock line.
Clause 15. The apparatus of clause 14, wherein the control logic triggers a restart function of the component in response to the output of the dynamic input comparator indicating the inconsistency is detected on the internal clock line.
Clause 16. The apparatus of clause 14 or 15, wherein the control logic triggers a shutdown of at least the component in response to the output of the dynamic input comparator indicating the inconsistency is detected on the internal clock line.
Clause 17. The apparatus of any of clauses 14-16, wherein the control logic triggers a change to a state of the component in response to the output of the dynamic input comparator indicating the inconsistency is detected on the internal clock line.
Clause 18. The apparatus of any of clauses 14-17, wherein the control logic triggers a change to stored data of the component in response to the output of the dynamic input comparator indicating the inconsistency is detected on the internal clock line.
Clause 19. The apparatus of any preceding clause, wherein the component has inputs for a plurality of external clock lines including the external clock line, the apparatus further comprising: at least one additional dynamic input comparator, each additional dynamic input comparator of the at least one additional dynamic input comparator coupled to the internal clock line and a corresponding additional external clock line of the plurality of external clock lines; and a logic gate coupled to the dynamic input comparator and the at least one additional dynamic input comparator to combine outputs of the dynamic input comparator and the at least one additional dynamic input comparator.
Clause 20. The apparatus of any of clauses 1-18, wherein the component has inputs for a plurality of external clock lines including the external clock line, the apparatus further comprising: a logic gate coupled to the plurality of external clock lines to combine signals from the plurality of external clock lines, wherein the dynamic input comparator is coupled at the second input to the external clock line of the component and to other external clock lines of the plurality of external clock lines via an output of the logic gate, whereby the dynamic input comparator detects the inconsistency on the internal clock line of the component with respect to the signal from the external clock line and any other signal from the other external clock lines of the plurality of external clock lines.

Although the subject matter has been described in language specific to structural features and/or acts, it is to be understood that the subject matter defined in the appended claims is not necessarily limited to the specific features or acts described above. Rather, the specific features and acts described above are disclosed as examples of implementing the claims and other equivalent features and acts are intended to be within the scope of the claims.

What is claimed is:

1. An apparatus comprising:
a dynamic input comparator structured to compare dynamic signals received at a first input and a second input to detect an inconsistency on an internal clock line of a component with respect to a signal from an external clock line, wherein the dynamic input comparator is coupled at the first input to the internal clock line and coupled at the second input to an external clock line of the component.

2. The apparatus of claim 1, wherein the internal clock line is coupled to clock circuitry that generates an internal clock signal on the internal clock line based on a signal from the external clock line.

3. The apparatus of claim 1, wherein the inconsistency on the internal clock line of the component with respect to the signal from the external clock line is a glitch on the internal clock line, a slew, or an inconsistent sequence of transitions.

4. The apparatus of claim 1, further comprising:
logic circuitry structured to combine an external clock signal with a component enable signal and output the signal from the external clock line, wherein the second input of the dynamic input comparator is coupled to the external clock line through the logic circuitry.

5. The apparatus of claim 1, wherein the dynamic input comparator comprises:
an edge detector circuit structured to receive an internal clock signal from the first input;
a first AND gate having an inverted input and a regular input; and
a second AND gate,
wherein an output of the edge detector circuit is coupled to the regular input of the first AND gate and one input of the second AND gate,
wherein the inverted input of the first AND gate and one other input of the second AND gate are coupled to the external clock line from the second input,
wherein a first output of the first AND gate indicates detection of an inconsistency on the internal clock line.

6. The apparatus of claim 5, wherein the edge detector circuit is a rising edge detector.

7. The apparatus of claim 5, wherein the edge detector circuit is a falling edge detector.

8. The apparatus of claim 5, wherein the edge detector circuit comprises a trim input including a LC filter, Schmitt trigger, or configurable delay chain.

9. The apparatus of claim 1, wherein the dynamic input comparator comprises:
a digital comparator;
a first storage unit coupled to the internal clock line from the first input to capture a value indicating a received pulse; and
a second storage unit coupled to the external clock line from the second input to capture a corresponding value indicating a received clock,
wherein the digital comparator compares the value stored in the first storage unit with the corresponding value from the second storage unit and outputs a non-matching signal when the value and the corresponding value do not match, wherein the non-matching signal indicates the inconsistency on the internal clock line.

10. The apparatus of claim 9, wherein the first storage unit and the second storage unit comprise latches.

11. The apparatus of claim 1, further comprising the component.

12. The apparatus of claim 11, wherein the component comprises memory circuitry.

13. The apparatus of claim 11, wherein the component comprises analog circuitry.

14. The apparatus of claim 1, further comprising:
control logic coupled to the dynamic input comparator to receive an output of the dynamic input comparator, the output of the dynamic input comparator indicating whether the inconsistency is detected on the internal clock line.

15. The apparatus of claim 14, wherein the control logic triggers a restart function of the component in response to the output of the dynamic input comparator indicating the inconsistency is detected on the internal clock line.

16. The apparatus of claim 14, wherein the control logic triggers a shutdown of at least the component in response to the output of the dynamic input comparator indicating the inconsistency is detected on the internal clock line.

17. The apparatus of claim 14, wherein the control logic triggers a change to a state of the component in response to the output of the dynamic input comparator indicating the inconsistency is detected on the internal clock line.

18. The apparatus of claim 14, wherein the control logic triggers a change to stored data of the component in response to the output of the dynamic input comparator indicating the inconsistency is detected on the internal clock line.

19. The apparatus of claim 1, wherein the component has inputs for a plurality of external clock lines including the external clock line, the apparatus further comprising:
at least one additional dynamic input comparator, each additional dynamic input comparator of the at least one additional dynamic input comparator coupled to the internal clock line and a corresponding additional external clock line of the plurality of external clock lines; and
a logic gate coupled to the dynamic input comparator and the at least one additional dynamic input comparator to combine outputs of the dynamic input comparator and the at least one additional dynamic input comparator.

20. The apparatus of claim 1, wherein the component has inputs for a plurality of external clock lines including the external clock line, the apparatus further comprising:
a logic gate coupled to the plurality of external clock lines to combine signals from the plurality of external clock lines, wherein the dynamic input comparator is coupled at the second input to the external clock line of the component and to other external clock lines of the plurality of external clock lines via an output of the logic gate, whereby the dynamic input comparator detects the inconsistency on the internal clock line of the component with respect to the signal from the external clock line and any other signal from the other external clock lines of the plurality of external clock lines.
